(19) United States
(12) Patent Application Publication
(10) Pub. No.: US 2026/0280324 A1
(43) Pub. Date: Sep. 17, 2026

(54) BATTERY SYSTEM

(71) Applicant: TOYOTA JIDOSHA KABUSHIKI KAISHA, Toyota-shi (JP)

(72) Inventors: Kenta ONISHI, Kariya-shi (JP); Hiroshi Yoshida, Anjo-shi (JP)

(73) Assignee: TOYOTA JIDOSHA KABUSHIKI KAISHA, Toyota-shi (JP)

(21) Appl. No.: 19/463,368

(22) Filed: Jan. 29, 2026

(30) Foreign Application Priority Data
Mar. 17, 2025 (JP) 2025-042079

(51) Int. Cl. H02J 7/80; G01R 31/36; G01R 31/364; G01R 31/3842; G01R 31/385; H02J 7/00; H02J 7/44

(52) U.S. Cl. CPC H02J 7/80; G01R 31/364; G01R 31/3648; G01R 31/3842; G01R 31/385; H02J 7/44; H02J 7/855

(57) ABSTRACT

A battery system includes a battery pack, a plurality of detection lines, and a monitoring device. A plurality of battery cells includes a first battery cell and a second battery cell. When the current flowing through the battery pack is smaller than a predetermined current value that flows during the ignition-off state, the monitoring device detects an abnormality in voltage detection based on an OCV difference, which is a difference between a first OCV of the first battery cell and a second OCV of the second battery cell. When an amount of variation in the current flowing through the battery pack is smaller than a predetermined current value that flows during external charging, the monitoring device detects an abnormality in voltage detection based on a CCV difference, which is a difference between a first CCV of the first battery cell and a second CCV of the second battery cell.

### CROSS-REFERENCE TO RELATED APPLICATION

This application claims priority to Japanese Patent Application No. 2025-042079 filed on March 17, 2025. The disclosure of the above-identified application, including the specification, drawings, and claims, is incorporated by reference herein in its entirety.

### BACKGROUND

### 1. Technical Field

The present disclosure relates to battery systems, and more particularly to a battery system capable of charging and discharging electric power.

### 2. Description of Related Art

Conventionally, there has been a technique for determining the voltage of each battery cell in a battery pack based on potentials detected by a plurality of detection lines for detecting the potentials of the respective battery cells (see, for example, Japanese Unexamined Patent Application Publication No. 2022-62882 (JP 2022-62882 A)).

### SUMMARY

In a battery system such as that disclosed in JP 2022-62882 A, it is conceivable that electric power is supplied to a processor that monitors the voltages of the battery cells by using a first detection line and a second detection line among a plurality of detection lines. In this case, an operating current of the processor flows through the first and second detection lines. Therefore, when the resistance value of either or both of these detection lines changes significantly due to an open circuit or a short circuit, the accuracy of voltage detection may be greatly affected.

The present disclosure has been made in view of the above circumstances, and an object thereof is to provide a battery system capable of detecting deterioration in voltage detection accuracy.

A battery system according to the present disclosure is configured to charge and discharge electric power, and includes: a battery pack in which a plurality of battery cells is connected in series; a plurality of detection lines each configured to detect a potential of a corresponding one of the battery cells; and a processor configured to monitor voltages of the battery cells each determined from potentials of corresponding ones of the detection lines. The battery cells include a first battery cell and a second battery cell. The processor is configured to detect an abnormality in voltage detection based on an open-circuit voltage difference when a current flowing through the battery pack is smaller than a predetermined small value. The open-circuit voltage difference is a difference between a first open-circuit voltage of the first battery cell and a second open-circuit voltage of the second battery cell. The processor is configured to detect an abnormality in voltage detection based on a closed-circuit voltage difference when an amount of variation in the current flowing through the battery pack is smaller than a predetermined amount. The closed-circuit voltage difference is a difference between a first closed-circuit voltage of the first battery cell and a second closed-circuit voltage of the second battery cell.

In this configuration, when the current flowing through the battery pack is smaller than the predetermined small value, an abnormality in voltage detection is detected based on the open-circuit voltage difference, which is the difference between the first open-circuit voltage of the first battery cell and the second open-circuit voltage of the second battery cell. When the amount of variation in the current flowing through the battery pack is smaller than the predetermined amount, an abnormality in voltage detection is detected based on the closed-circuit voltage difference, which is the difference between the first closed-circuit voltage of the first battery cell and the second closed-circuit voltage of the second battery cell. It is therefore possible to provide a battery system capable of detecting deterioration in voltage detection accuracy.

The detection lines may include: a first detection line electrically connected to a first electrode of the first battery cell; a second detection line electrically connected to a second electrode of the first battery cell that is different from the first electrode, and to a first electrode of the second battery cell; and a third detection line electrically connected to a second electrode of the second battery cell. The processor may be configured to: calculate, as the first closed-circuit voltage, a difference between a potential detected by the first detection line and a potential detected by the second detection line; calculate, as the second closed-circuit voltage, a difference between the potential detected by the second detection line and a potential detected by the third detection line; and calculate the closed-circuit voltage difference based on the first closed-circuit voltage and the second closed-circuit voltage. The processor may be configured to: acquire, for each predetermined sampling period, a first combination of the first closed-circuit voltage and a current flowing through the first battery cell, and a second combination of the second closed-circuit voltage and a current flowing through the second battery cell, to obtain a predetermined number of the first combinations and a predetermined number of the second combinations; calculate internal resistances of the first battery cell and the second battery cell from the predetermined number of the first combinations and the predetermined number of the second combinations, respectively; calculate, using the internal resistances, the first open-circuit voltage and the second open-circuit voltage from the first closed-circuit voltage and the second closed-circuit voltage, respectively; and calculate the open-circuit voltage difference from the first open-circuit voltage and the second open-circuit voltage.

In this configuration, the difference between the potential detected by the first detection line and the potential detected by the second detection line is calculated as the first closed-circuit voltage, the difference between the potential detected by the second detection line and the potential detected by the third detection line is calculated as the second closed-circuit voltage, and the closed-circuit voltage difference is calculated based on the first closed-circuit voltage and the second closed-circuit voltage. A first combination of the first closed-circuit voltage and the current flowing through the first battery cell and a second combination of the second closed-circuit voltage and the current flowing through the second battery cell are acquired for each predetermined sampling period to obtain the predetermined number of the first combinations and the predetermined number of the second combinations. The internal resistances of the first battery cell and the second battery cell are calculated from the predetermined number of the first combinations and the predetermined number of the second combinations, respectively. Using the calculated internal resistances, the first open-circuit voltage and the second open-circuit voltage are calculated from the first closed-circuit voltage and the second closed-circuit voltage, respectively. The open-circuit voltage difference is calculated from the calculated first and second open-circuit voltages. As a result, the open-circuit voltage difference can be appropriately calculated.

The processor may be configured to operate using, as a power source, a potential difference between one of the first detection line and the third detection line and another detection line that is different from the one detection line among the detection lines. When electric power for the processor is supplied from a detection line, the operating current of the processor flows through that detection line. Therefore, when the resistance value of that detection line changes significantly, the accuracy of voltage detection may be greatly affected. With this configuration, deterioration in voltage detection accuracy can be detected even when electric power for the processor is supplied from a detection line.

The detection line may include a terminal portion of the battery cell, a portion of a flexible printed circuit connected to the terminal portion, and a wire portion connecting the flexible printed circuit and the processor, and a power line of the processor may branch off from the wire portion.

With this configuration, the connectors of the flexible printed circuit can be made smaller as compared with a case where the power line branches off from a portion other than the wire portion. This configuration also allows the connectors to be used without changing terminal arrangements between the detection line and the power line. As a result, the manufacturing cost can be reduced.

The present disclosure can provide a battery system capable of detecting deterioration in voltage detection accuracy.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing the overall configuration of an electrified vehicle equipped with a battery system according to an embodiment of the present disclosure;

FIG. 2 is a diagram schematically showing the configuration of the battery system according to the embodiment;

FIG. 3 is a flowchart of an abnormality detection process according to the embodiment;

FIG. 4 shows graphs illustrating a method for calculating an open-circuit voltage (OCV) difference according to the embodiment;

FIG. 5A is a graph illustrating a method for detecting an abnormality in voltage detection when the current flowing through battery cells is small according to the embodiment;

FIG. 5B is a diagram illustrating the method for detecting an abnormality in voltage detection when the current flowing through the battery cells is small according to the embodiment;

FIG. 5C is a graph illustrating the method for detecting an abnormality in voltage detection when the current flowing through the battery cells is small according to the embodiment;

FIG. 6A is a graph illustrating a method for detecting an abnormality in voltage detection when the variation in the current flowing through the battery cells is small according to the present embodiment; and

FIG. 6B is a graph illustrating the method for detecting an abnormality in voltage detection when the variation in the current flowing through the battery cells is small according to the present embodiment.

### DETAILED DESCRIPTION OF EMBODIMENTS

An embodiment of the present disclosure will be described in detail below with reference to the drawings. The same or corresponding portions are denoted by the same signs throughout the drawings, and description thereof will not be repeated.

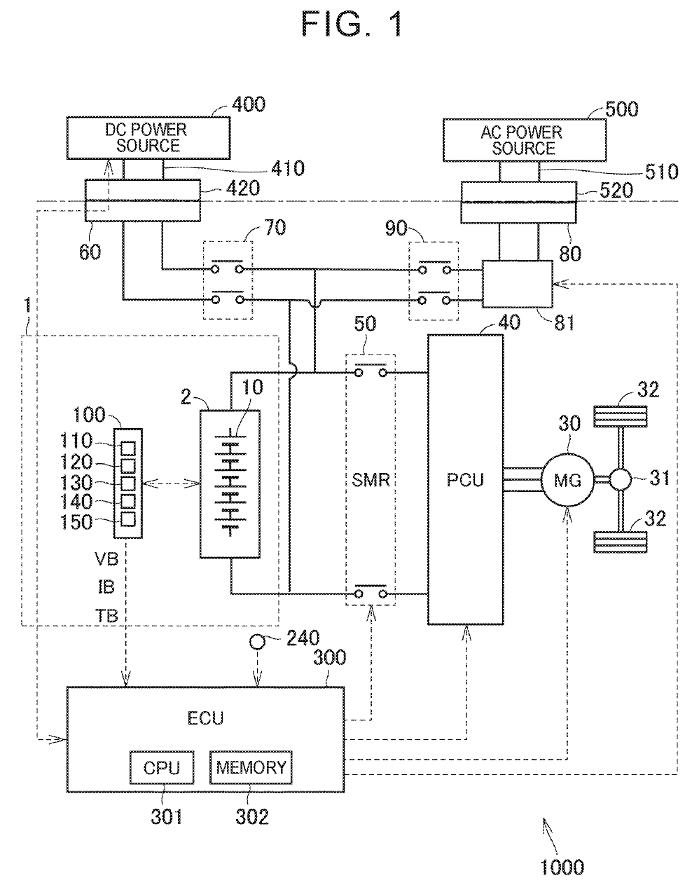

FIG. 1 shows the overall configuration of an electrified vehicle 1000 equipped with a battery system 1 according to the present embodiment. In the present embodiment, the electrified vehicle 1000 is, for example, a battery electric vehicle. The electrified vehicle 1000 includes a motor generator (MG) 30 that is a rotating electrical machine, a power transmission gear 31, drive wheels 32, a power control unit (PCU) 40, a system main relay (SMR) 50, a battery pack 2, a monitoring device 100 that monitors the battery pack 2, and an electronic control unit (ECU) 300 that controls the electrified vehicle 1000. The battery system 1 includes the battery pack 2 and the monitoring device 100.

The MG 30 is, for example, an interior permanent magnet synchronous motor (IPM motor), and functions as both an electric motor and a generator. The output torque of the MG 30 is transmitted to the drive wheels 32 via the power transmission gear 31 that includes, for example, a reduction gear and a differential.

During braking of the electrified vehicle 1000, the MG 30 is driven by the drive wheels 32 and operates as a generator. Accordingly, the MG 30 also functions as a braking device that performs regenerative braking to covert the kinetic energy of the electrified vehicle 1000 into electric power. The regenerative power generated by the regenerative braking of the MG 30 is stored in the battery pack 2.

The PCU 40 is a power conversion device that bidirectionally converts electric power between the MG 30 that operates on alternating current power and the battery pack 2 that stores direct current power. The PCU 40 includes, for example, an inverter and a converter that operate based on control signals from the ECU 300.

During discharge of the battery pack 2, the converter boosts the voltage supplied from the battery pack 2 and supplies the boosted voltage to the inverter. The inverter converts the direct current power supplied from the converter to alternating current power to drive the MG 30.

On the other hand, during charging of the battery pack 2, the inverter converts the alternating current power generated by the MG 30 into direct current power and supplies it to the converter. The converter steps down the voltage supplied from the inverter to a level suitable for charging the battery pack 2 and supplies the stepped-down voltage to the battery pack 2.

The SMR 50 is electrically connected to a power line that connects the battery pack 2 and the PCU 40. When the SMR 50 is closed (ON) in response to a control signal from the ECU 300 (that is, when the SMR 50 is in a conducting state), electric power can be transferred between the battery pack 2 and the PCU 40. When the SMR 50 is open (OFF) in response to a control signal from the ECU 300, (that is, when the SMR 50 is in a non-conducting state), the electrical connection between the battery pack 2 and the PCU 40 is interrupted.

The battery pack 2 stores electric power used to drive the MG 30. The battery pack 2 serves as a rechargeable direct current power source (secondary battery) and is formed of a stack of a plurality of battery cells 10 that is, for example, electrically connected in series. The battery cells 10 may be, for example, lithium-ion cells. However, the present disclosure is not limited to this. The battery cells 10 may instead be other types of cells such as nickel metal hydride cells or all-solid-state cells.

The monitoring device 100 includes a processor 110, a memory 120, a voltage detection unit 130, a current sensor 140, and a temperature sensor 150. The voltage detection unit 130 detects the voltage VB of each battery cell 10 (i.e., the voltage VB between the terminals of each battery cell 10). The current sensor 140 detects the current IB flowing into and out of the battery pack 2 (the battery cells 10). The temperature sensor 150 detects the temperature TB of each battery cell 10. The detection results from these detection units are processed by the processor 110 and then output to the ECU 300.

The electrified vehicle 1000 is equipped with a direct current (DC) inlet 60, and the battery pack 2 can be rapidly charged from an external DC power source that serves as charging equipment. The DC inlet 60 is configured to be connectable with a connector 420 provided at a distal end of a charging cable 410 of an external DC power source (charging equipment) 400. A charging relay 70 is electrically connected to a power line that connects the DC inlet 60 and the battery pack 2. The charging relay 70 selectively supplies or interrupts electric power between the DC inlet 60 and the battery pack 2 in response to a control signal from the ECU 300. When the charging relay 70 is closed, external charging (rapid charging) of the battery pack 2 is performed.

The electrified vehicle 1000 is also equipped with an alternating current (AC) inlet 80, and the battery pack 2 can be normally charged from an external AC power source that serves as charging equipment. The AC inlet 80 is configured to be connectable with a connector 520 provided at a distal end of a charging cable 510 of an external AC power source (charging equipment) 500. An in-vehicle charger 81 is provided on a power line between the AC inlet 80 and the battery pack 2. The in-vehicle charger 81 converts the alternating current power supplied from the external AC power source into direct current power and converts the voltage to a level suitable for charging the battery pack 2. A charging relay 90 is electrically connected to a power line that connects the in-vehicle charger 81 and the battery pack 2. The charging relay 90 selectively supplies or interrupts electric power between the in-vehicle charger 81 and the battery pack 2 in response to a control signal from the ECU 300. When the charging relay 90 is closed, external charging (normal charging) of the battery pack 2 is performed.

The ECU 300 includes a central processing unit (CPU) 301 and a memory 302 (including, for example, a read-only memory (ROM) and a random access memory (RAM)). The ECU 300 controls various devices such that the electrified vehicle 1000 attains a desired state, based on signals received from the monitoring device 100, signals from various sensors (for example, an accelerator operation amount signal and a vehicle speed signal), and information such as maps and programs stored in the memory 302.

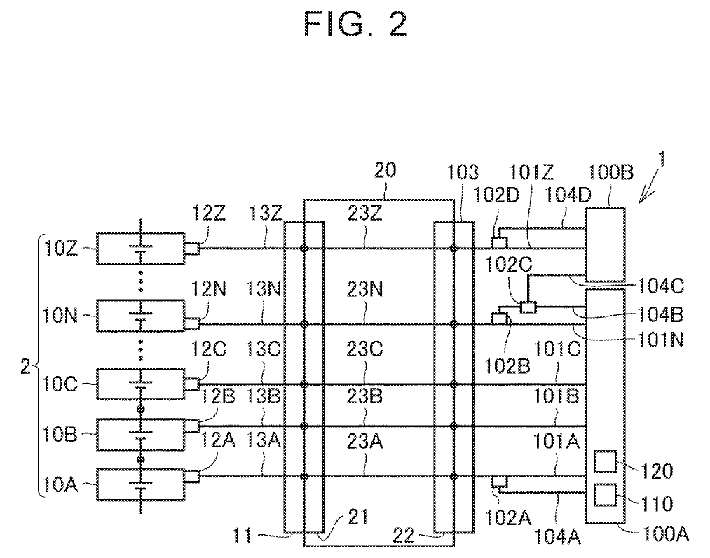

FIG. 2 schematically shows the configuration of the battery system 1 according to the present embodiment. Referring to FIG. 2, the battery system 1 includes a flexible printed circuit ("FPC") 20, in addition to the battery pack 2 and at least one monitoring device 100A, 100B (hereinafter collectively referred to as "monitoring device 100" as a representative example) as the monitoring device 100 shown in FIG. 1. The battery pack 2 includes, as the battery cells 10 described above, a plurality of battery cells 10A to 10Z connected in series.

The monitoring device 100 includes a processor 110 and a memory 120, and monitors, for example, the voltage, current, and temperature of each battery cell 10. The monitoring device 100 transmits the monitoring results to another device, for example, to a vehicle electronic control unit (ECU) when the battery system 1 is mounted on a vehicle as a traction battery system.

The FPC 20 connects the battery pack 2 and the monitoring device 100. The FPC 20 includes a connector 21 for connection to the battery pack 2, a connector 22 for connection to the monitoring device 100, and circuits 23A to 23Z (hereinafter also collectively referred to as "circuits 23"). Each circuit 23 is provided with circuit components such as fuses, capacitors, inductors, and diodes. One end of each circuit 23 is connected to the connector 21, and the other end of each circuit 23 is connected to the connector 22.

Battery cells 10A to 10Z are respectively provided with terminals 12A to 12Z (hereinafter also collectively referred to as "terminals 12"). Each of the terminals 12A to 12Z is connected to one end of a corresponding one of voltage detection lines 13A to 13Z (hereinafter also collectively referred to as "voltage detection lines 13"). The terminals 12A to 12Z are electrically connected to the positive terminals of the battery cells 10A to 10Z, respectively. A connector 11 is provided at the other ends of the voltage detection lines 13A to 13Z. The connector 11 mates with the connector 21 of the FPC 20.

The voltage detection lines 13A to 13Z are respectively connected to the circuits 23A to 23Z via the connectors 11, 21. The monitoring device 100 is connected to one ends of voltage detection lines 101A to 101Z (hereinafter also collectively referred to as "voltage detection lines 101"). A connector 103 is provided at the other ends of the voltage detection lines 101A to 101Z. The connector 103 mates with the connector 22 of the FPC 20.

In this manner, the voltage detection lines, each including the voltage detection line 13, the circuit 23, and the voltage detection line 101, connect the battery cells 10 and the monitoring device 100. This allows the monitoring device 100 to determine the voltages of the battery cells 10 based on the potentials of the battery cells 10 detected by these voltage detection lines.

In such a battery system 1, electric power may be supplied to the monitoring device 100A that monitors the voltages of the battery cells 10, using a first detection line (for example, a voltage detection line including the voltage detection line 13A, the circuit 23A, and the voltage detection line 101A) and a second detection line (for example, a voltage detection line including the voltage detection line 13N, the circuit 23N, and the voltage detection line 101N) among the multiple voltage detection lines.

A power line 104A branches off from the voltage detection line 101A at a branch connector 102A. A power line 104B branches off from the voltage detection line 101N at a branch connector 102B. The monitoring device 100A operates using electric power corresponding to the potential difference between the power lines 104A, 104B.

A power line 104C branches off from the power line 104B at a branch connector 102C. A power line 104D branches off from the voltage detection line 101Z at a branch connector 102D. The monitoring device 100B operates using electric power corresponding to the potential difference between the power lines 104C, 104D.

In this case, an operating current of the monitoring device 100A flows through the first and second detection lines. Therefore, when the resistance value of either or both of these detection lines changes significantly due to an open circuit or a short circuit, the accuracy of voltage detection may be greatly affected. For example, the resistance value of a voltage detection line may change when any of the connectors 11, 21, 22, 103 is partially fitted, when a foreign substance becomes caught in any of the connectors 11, 21, 22, 103, when plating on a connection portion of any of the connector 11, 21, 22, 103 peels off, or when variations occur in the manufacturing quality of the voltage detection lines.

Accordingly, the monitoring device 100A calculates an open-circuit voltage difference, which is the difference between a first open-circuit voltage of the battery cell 10A detected by the first detection line and a second open-circuit voltage of the battery cell 10N detected by the second detection line. When a variation in the open-circuit voltage difference during a predetermined period is greater than or equal to a prescribed value, the monitoring device 100A determines that an abnormality in voltage detection has occurred.

Thus, when the open-circuit voltage difference, which is the difference between the first open-circuit voltage of the battery cell 10A detected by the first detection line and the second open-circuit voltage of the battery cell 10N detected by the second detection line, is calculated and the variation in the open-circuit voltage difference during the predetermined period is greater than or equal to the prescribed value, an abnormality in voltage detection is determined to have occurred. As a result, deterioration in voltage detection accuracy can be detected.

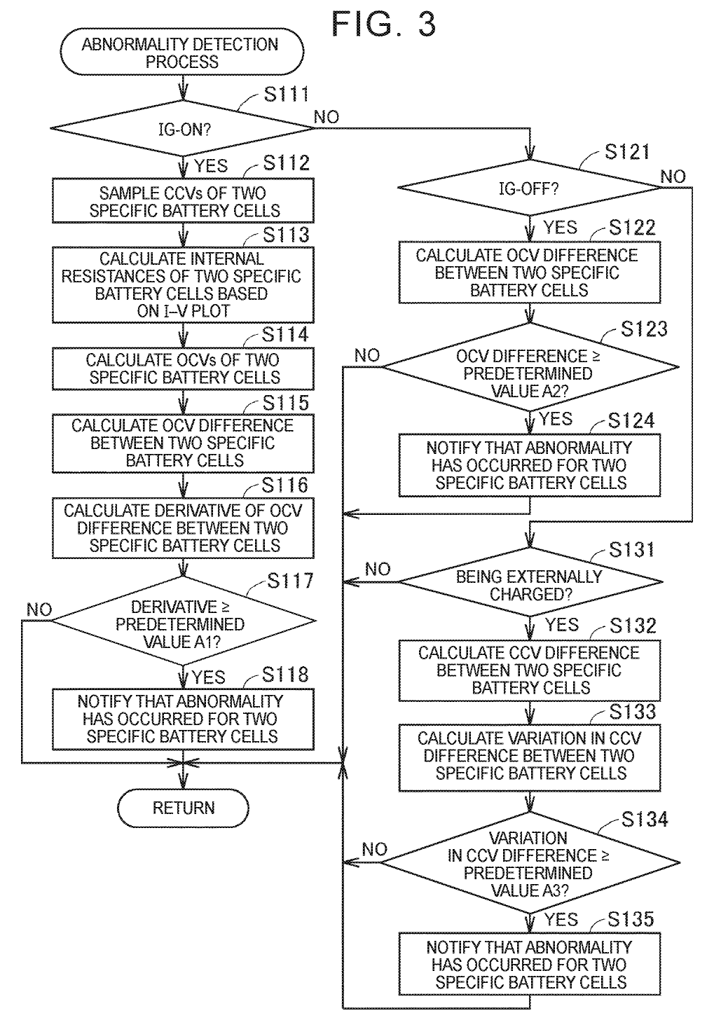

FIG. 3 is a flowchart of an abnormality detection process according to the present embodiment. Referring to FIG. 3, this abnormality detection process is executed by the processor 110 of the monitoring device 100 at predetermined intervals when called from a higher-level process.

The processor 110 of the monitoring device 100 determines whether the electrified vehicle 1000 is in the ignition-on state (that is, in the state where the power switch is on, the ready mode is on, and the battery pack 2 is energized) (step S111). When it is determined that the electrified vehicle 1000 is in the ignition-on state (YES in step S111), the processor 110 of the monitoring device 100 samples the closed-circuit voltages (hereinafter referred to as "CCVs") of two specific battery cells 10 and the current (step S112). For example, when the two specific battery cells 10 are the battery cell 10C and the battery cell 10B, sampling is performed as follows. For the battery cell 10C, the potential difference between the terminal 12C and the terminal 12B is sampled as the CCV of the battery cell 10C. For the battery cell 10B, the potential difference between the terminal 12B and the terminal 12A is sampled as the CCV of the battery cell 10B.

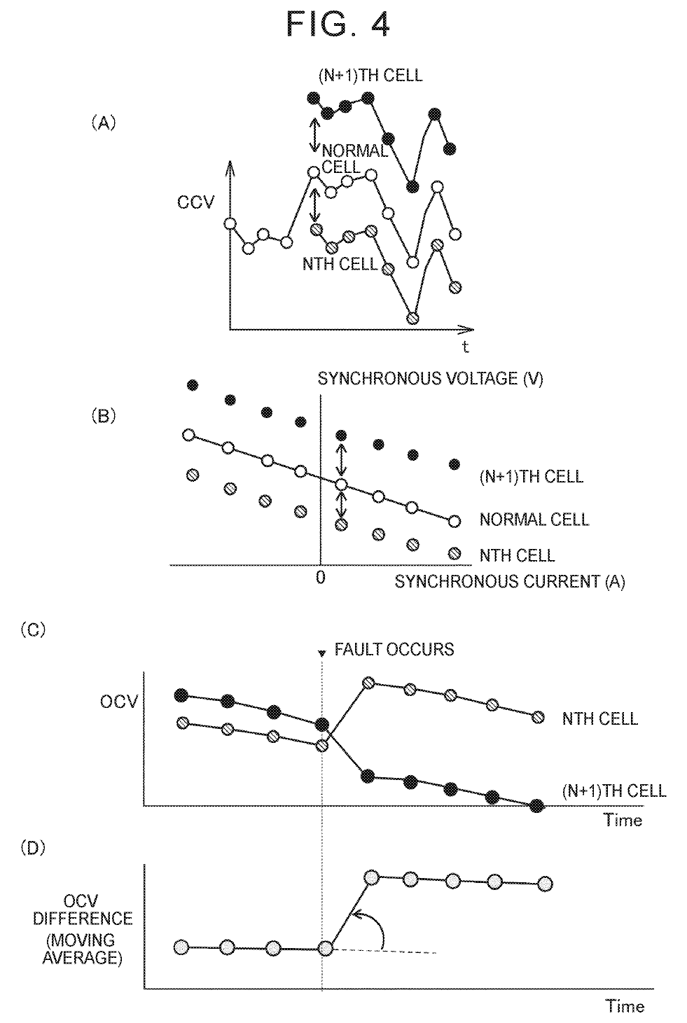

FIG. 4 shows graphs illustrating a method for calculating the open-circuit voltage (OCV) difference according to the present embodiment. In (A) of FIG. 4, the horizontal axis represents time and the vertical axis represents voltage. The graph in (A) of FIG. 4 shows changes in the CCV of the battery cell 10. The middle graph shows the change in the CCV of a normal battery cell 10 in which no abnormality has occurred. The upper and lower graphs respectively show the changes in the CCVs of two adjacent battery cells 10 (the nth and (n+1)th battery cells 10 of the battery pack 2) when an abnormality has occurred. Each plotted point represents a combination of the sampling time and the corresponding CCV.

Returning to FIG. 3, the processor 110 of the monitoring device 100 calculates the internal resistances of the two specific battery cells 10 based on the I–V plot (step S113).

Referring again to FIG. 4, the horizontal axis in (B) of FIG. 4 represents current, and the vertical axis represents voltage. The white circles in (B) of FIG. 4 represent combinations of current and CCV for a predetermined number of sampling cycles (eight in this example) in a normal battery cell 10 in which no abnormality has occurred. Note that the predetermined number multiplied by the sampling period equals T1 seconds. The hatched and black circles respectively represent combinations of current and CCV for the predetermined number of sampling cycles of the two adjacent battery cells 10 (the nth and (n+1)th battery cells 10 of the battery pack 2) when an abnormality has occurred. Approximate straight lines are obtained from these plotted points by the least-squares method. The slope of each approximate straight line corresponds to the internal resistance of the respective battery cell 10. The internal resistance of each battery cell 10 can thus be calculated. Errors in the IR component can be canceled out by the least-squares method.

Returning again to FIG. 3, the processor 110 of the monitoring device 100 calculates the OCVs of the two specific battery cells 10 using the CCVs, currents, and internal resistances of the two specific battery cells 10 (step S114). The OCVs are calculated using the formula OCV = CCV + (current × internal resistance). Next, the processor 110 of the monitoring device 100 calculates the OCV difference between the two specific battery cells 10 (step S115). The processor 110 of the monitoring device 100 then calculates a moving average and a derivative of the calculated OCV difference (step S116).

Referring again to FIG. 4, the vertical axis in (C) of FIG. 4 represents voltage, in units of volts (V). The graph in (C) of FIG. 4 shows changes in the OCVs calculated from the I–V plot. The two graphs respectively indicate changes in the OCVs of the two adjacent battery cells 10 (that is, the nth and (n+1)th battery cells 10 of the battery pack 2) when an abnormality has occurred.

The vertical axis in (D) of FIG. 4 also represents voltage, in units of volts (V). The graph in (D) of FIG. 4 shows changes in the OCV difference between the two adjacent battery cells 10. This graph indicates changes in the moving average of the OCV difference between the two adjacent battery cells 10 (that is, the nth and (n+1)th battery cells 10 of the battery pack 2) when an abnormality has occurred. The moving average of the OCV difference is differentiated. Errors in the absolute value of the OCV can be canceled out by differentiation.

As shown in FIG. 4, when a fault occurs in a voltage detection line of a battery cell 10, both the OCV and (the moving average of) the OCV difference change significantly. Therefore, an abnormality in voltage detection can be detected based on the derivative of the OCV difference.

Returning to FIG. 3, the processor 110 of the monitoring device 100 determines whether the derivative of the OCV difference between the two specific battery cells 10 is greater than or equal to a predetermined value A1 (step S117). When it is determined that the derivative is greater than or equal to the predetermined value A1 (YES in step S117), the processor 110 of the monitoring device 100 notifies an external device (for example, the ECU 300) that an abnormality in voltage detection has occurred for the two specific battery cells 10 (step S118). When it is determined that the derivative is smaller than the predetermined value A1 (NO in step S117), or after step S118, the processor 110 of the monitoring device 100 returns control to the higher-level process that called this abnormality detection process.

When it is determined that the electrified vehicle 1000 is not in the ignition-on state (NO in step S111), the processor 110 of the monitoring device 100 determines whether the electrified vehicle 1000 is in the ignition-off state (that is, in the state where the power switch is off and the ready mode is off) (step S121). When it is determined that the electrified vehicle 1000 is in the ignition-off state (YES in step S121), the processor 110 of the monitoring device 100 calculates the OCV difference between the two specific battery cells 10 (step S122).

In this state, since the electrified vehicle 1000 is in the ignition-off state, almost no current flows through the battery pack 2 (battery cells 10). Therefore, the CCV is regarded as the OCV, and the difference between the CCVs of the two specific battery cells 10 is calculated as the OCV difference. However, the present disclosure is not limited to this. The OCV difference between the two specific battery cells 10 may alternatively be calculated in the same manner as in steps S112 to S115 described above.

The processor 110 of the monitoring device 100 determines whether the OCV difference is greater than or equal to a predetermined value A2 (step S123). When it is determined that the OCV difference is greater than or equal to the predetermined value A2 (YES in step S123), the processor 110 of the monitoring device 100 notifies an external device (for example, the ECU 300) that an abnormality in voltage detection has occurred for the two specific battery cells 10 (step S124). When it is determined that the OCV difference is smaller than the predetermined value A2 (NO in step S123), or after step S124, the processor 110 of the monitoring device 100 returns control to the higher-level process that called this abnormality detection process.

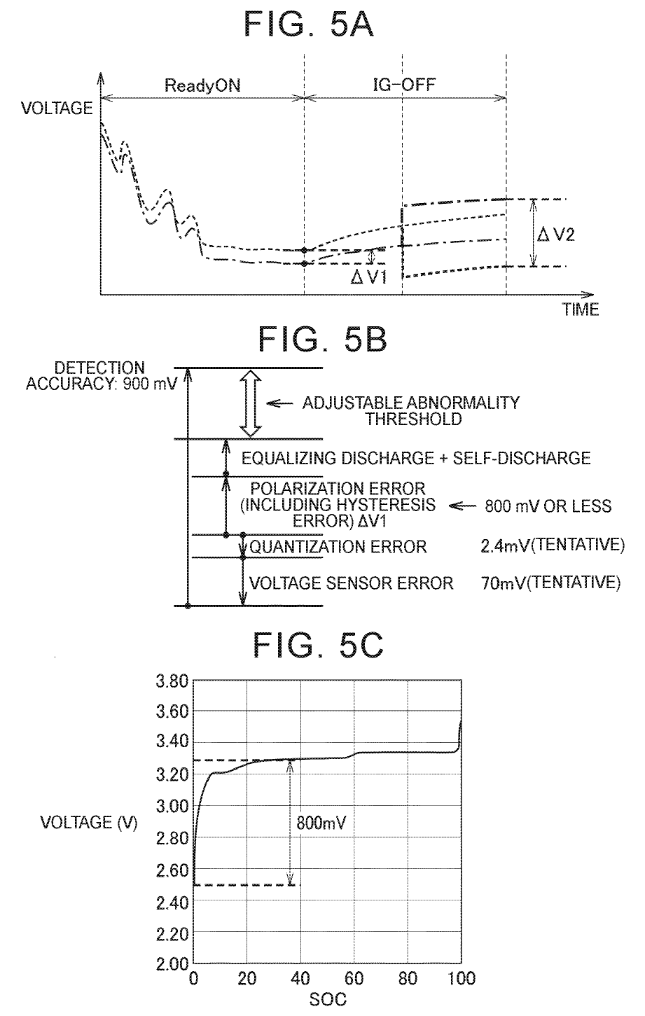

FIGS. 5A, 5B, and 5C are diagrams illustrating a method for detecting an abnormality in voltage detection when the current flowing through the battery cells 10 is small according to the present embodiment. Referring to FIGS. 5A, 5B, and 5C, the horizontal axis in FIG. 5A represents time, and the vertical axis represents voltage. The two graphs in FIG. 5A respectively show changes in the OCVs of the two specific battery cells 10. The OCV difference when the ignition is switched from ON to OFF is denoted as ΔV1. When an abnormality occurs in either or both of the two battery cells 10 during the ignition-off period, the OCV difference becomes ΔV2. By setting the predetermined value A2 to a value between ΔV1 and ΔV2, it is possible to detect that an abnormality in voltage detection has occurred for the two specific battery cells 10.

FIG. 5B shows an example of how the predetermined value A2 is determined. For example, the predetermined value A2 can be determined by adding to ΔV1 the sum of (i) the voltage decrease caused by equalizing discharge and self-discharge (which has little effect when the ignition is off), (ii) the voltage error generated when the voltage detected by the voltage detection unit 130 is quantized from an analog value to a digital value, and (iii) the voltage detection error of the voltage detection unit 130, and further adding an appropriately set threshold for determining an abnormality.

FIG. 5C shows the SOC–OCV curve of a battery cell 10. In a battery cell 10, the maximum voltage difference at a low state of charge (SOC) as shown in FIG. 5C is, for example, 800 mV. When the two specific battery cells 10 are normal, ΔV1 is not expected to exceed 800 mV. Therefore, as shown in FIG. 5B, ΔV1 may be set to 800 mV when calculating the predetermined value A2. In FIG. 5B, assuming that ΔV1 is 800 mV, the quantization error is 2.4 mV, the voltage sensor error is 70 mV, and the threshold is set to 27.6 mV, the accuracy for detecting a voltage detection abnormality can be set to 900 mV. This value can be used as the predetermined value A2.

Returning to FIG. 3, when it is determined that the electrified vehicle 1000 is not in the ignition-off state (NO in step S121), the processor 110 of the monitoring device 100 determines whether the electrified vehicle 1000 is being externally charged (step S131). When it is determined that the electrified vehicle 1000 is being externally charged (YES in step S131), the processor 110 of the monitoring device 100 calculates the CCV difference between the two specific battery cells 10 (step S132).

In this state, since the electrified vehicle 1000 is being externally charged, the current flowing through the battery pack 2 (the battery cells 10) is expected to remain constant for a long period. Therefore, the CCV difference can be regarded as approximately equal to the OCV difference. Accordingly, it is possible to detect that an abnormality in voltage detection has occurred for the two specific battery cells 10, based on the CCV difference between these battery cells.

Next, the processor 110 of the monitoring device 100 calculates the variation in the CCV difference between the two specific battery cells 10 (step S133). The processor 110 of the monitoring device 100 then determines whether the variation in the CCV difference is greater than or equal to a predetermined value A3 (step S134). When it is determined that the variation in the CCV difference is greater than or equal to the predetermined value A3 (YES in step S134), the processor 110 of the monitoring device 100 notifies an external device (for example, the ECU 300) that an abnormality in voltage detection has occurred for the two specific battery cells 10 (step S135). When it is determined that the electrified vehicle 1000 is not being externally charged (NO in step S131), or that the variation in the CCV difference is smaller than the predetermined value A3 (NO in step S134), or after step S135, the processor 110 of the monitoring device 100 returns control to the higher-level process that called this abnormality detection process.

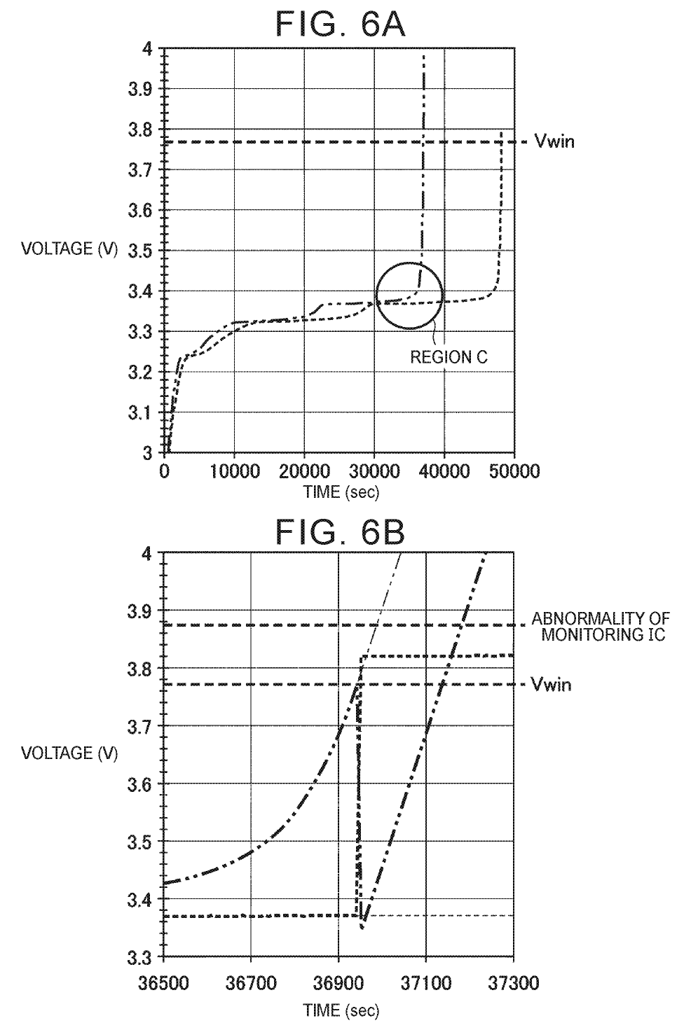

FIGS. 6A and 6B are graphs illustrating a method for detecting an abnormality in voltage detection when the variation in the current flowing through the battery cells 10 is small according to the present embodiment. In FIGS. 6A and 6B, the horizontal axis represents time, and the vertical axis represents voltage. FIG. 6A shows the SOC–OCV curves of a battery cell 10. The dashed line in FIG. 6A represents an example of a typical SOC–OCV curve of a battery cell 10. The long dashed double-short dashed line in FIG. 6A represents an example of an SOC–OCV curve of a battery cell 10 exhibiting characteristic variation.

As shown in FIG. 6B, when an abnormality in voltage detection occurs in region C of FIG. 6A, the voltage of the nth battery cell 10 drops sharply when it reaches the voltage corresponding to the charging power limit value Win. Accordingly, the voltage of the (n+1)th battery cell 10 rises sharply. In this case, since the electrified vehicle 1000 is being externally charged, the current flowing through the battery cells 10 can be regarded as constant. Accordingly, the difference between the OCVs of the nth and (n+1)th battery cells 10 can be considered to be approximately equal to the difference between their CCVs. When the variation in this CCV difference is greater than or equal to the predetermined value A3, it can be determined that an abnormality in voltage detection has occurred.

### Modifications

(1) In the above embodiment, the battery system 1 is configured as shown in FIG. 2. In the battery system 1, the power lines 104A, 104B and 104C, and 104D that supply electric power to the monitoring device 100 respectively branch off from the voltage detection lines 101A, 101N, and 101Z that are closest to the monitoring device 100. However, the present disclosure is not limited to this configuration. The power lines that supply electric power to the monitoring device 100 may instead branch off from other portions of the voltage detection lines.

For example, the power lines 104A to 104D that supply electric power to the monitoring device 100 may be connected to additional terminals that are provided on the battery cells 10 in addition to the terminals 12. In this case, since the power lines 104A to 104D pass through the FPC 20, additional circuits for the power lines 104A to 104D are provided on the FPC 20. In addition, connection portions for the power lines 104A to 104D are provided on the connectors 21, 22 of the FPC 20 and the connectors 11, 103 that are respectively connected to the connectors 21, 22.

Alternatively, the power lines 104A to 104D that supply electric power to the monitoring device 100 may branch off from the circuits 23A, 23N, 23Z of the FPC 20. In this case as well, since the power lines 104A to 104D pass through the FPC 20, additional circuits for the power lines 104A to 104D are provided on the FPC 20. In addition, connection portions for the power lines 104A to 104D are provided on the connector 22 of the FPC 20 and the connector 103 connected to the connector 22. However, connection portions for the power lines 104A to 104D are not provided on the connector 21 of the FPC 20 and the connector 11 connected to the connector 21. Furthermore, no additional terminals are provided on the battery cells 10.

In contrast, in the battery system 1 of the above embodiment shown in FIG. 1, additional circuits for the power lines 104A to 104D are not provided on the FPC 20. Connection portions for the power lines 104A to 104D are not provided on the connectors 21, 22 of the FPC 20 and the connectors 11, 103 that are respectively connected to the connectors 21, 22. Furthermore, no additional terminals are provided on the battery cells 10. Therefore, when the power lines 104A to 104D branch off from the voltage detection lines 101A, 101N, 101Z that are closest to the monitoring device 100 as in the embodiment shown in FIG. 1, the FPC 20 and the connectors 21, 22 of the FPC 20 can be made simpler and smaller as compared with a case where the power lines branch off from other portions. This configuration also allows the connectors to be used without changing terminal arrangements between the voltage detection lines and the power lines. As a result, the manufacturing cost of the battery system 1 can be reduced.

(2) In the above embodiment, as shown in FIG. 2, three voltage detection lines connected to three adjacent terminals 12 (for example, the terminals 12A to 12C) are used to calculate the OCVs of two specific battery cells 10 (for example, the battery cells 10A, 10B). The power line (for example, the power line 104A) for the monitoring device 100 branches off from one of these three voltage detection lines (for example, the voltage detection line connected to the terminal 12A). When electric power for the monitoring device 100 is supplied from a voltage detection line, the operating current of the monitoring device 100 flows through that voltage detection line. Therefore, when the resistance value of that voltage detection line changes significantly, the accuracy of voltage detection of the monitoring device 100 may be greatly affected. According to the embodiment, even when electric power for the monitoring device 100 is supplied from a voltage detection line, deterioration in voltage detection accuracy can be detected as described above. However, the present disclosure is not limited to this configuration. The power lines may instead be arranged so as not to branch off from any of the three voltage detection lines.

(3) In the above embodiment, as described with reference to FIG. 1, the terminals 12A to 12Z are electrically connected to the positive terminals of the battery cells 10A to 10Z, respectively. However, the present disclosure is not limited to this configuration. The terminals 12A to 12Z may instead be electrically connected to the negative terminals of the battery cells 10A to 10Z, respectively.

(4) In the above embodiment, as shown in steps S112 to S117, an abnormality in voltage detection during the ignition-on state is determined based on how the OCV difference varies. However, the present disclosure is not limited to this configuration. An abnormality in voltage detection during the ignition-on state may be determined by other methods. For example, it may be determined based on the magnitude of the OCV difference or on the amount of variation in the OCV difference.

(5) In the above embodiment, as shown in steps S122 to S123, an abnormality in voltage detection during the ignition-off state is determined based on the magnitude of the OCV difference. However, the present disclosure is not limited to this configuration. An abnormality in voltage detection during the ignition-off state may be determined by other methods. For example, it may be determined based on how the OCV difference varies (for example, how the OCV difference changes from the value in the previous trip) or on the amount of variation in the OCV difference (for example, the amount of variation in the OCV difference relative to the value in the previous trip).

(6) In the above embodiment, as shown in steps S132 to S134, an abnormality in voltage detection during external charging is determined based on the amount of variation in the CCV difference. However, the present disclosure is not limited to this configuration. An abnormality in voltage detection during external charging may be determined by other methods. For example, it may be determined based on the magnitude of the CCV difference or on how the CCV difference varies.

(7) In the above embodiment, the abnormality detection process shown in FIG. 3 is executed by the processor 110 of the monitoring device 100. However, the present disclosure is not limited to this configuration. The abnormality detection process may instead be executed by another control device such as the CPU 301 of the ECU 300.

(8) In the above embodiment, the electrified vehicle 1000 is a battery electric vehicle. However, the present disclosure is not limited to this. The electrified vehicle 1000 may be any type of electrified vehicle that can be externally charged. For example, it may be a plug-in hybrid electric vehicle or a fuel cell electric vehicle that can be externally charged.

(9) The above embodiment can be regarded as a disclosure of a charging system for the battery pack 2 such as the battery system 1, as a disclosure of a vehicle such as the electrified vehicle 1000 equipped with such a charging system, as a disclosure of a control device such as the monitoring device 100 of the charging system, or as a disclosure of a charging method or charging program executed by the charging system, the vehicle, or the control device.

### Summary

(1) As shown in FIGS. 1 and 2, the battery system 1 is configured to charge and discharge electric power and includes: the battery pack 2 in which the battery cells 10 is connected in series; the detection lines (for example, the voltage detection lines each including the voltage detection line 13, the circuit 23, and the voltage detection line 101) configured to detect the potentials of the respective battery cells 10; and the monitoring device 100 that monitors the voltages of the respective battery cells 10 as determined from the potentials of the corresponding detection lines. As shown in FIG. 2, the battery cells 10 include a first battery cell and a second battery cell (for example, the battery cells 10B, 10C). As shown in FIGS. 2 to 6A and 6B, when the current flowing through the battery pack 2 is smaller than a predetermined small value (for example, a predetermined current value that flows during the ignition-off state), the monitoring device 100 detects an abnormality in voltage detection based on the OCV difference, which is the difference between a first OCV of the first battery cell and a second OCV of the second battery cell (for example, steps S121 to S124). When the amount of variation in the current flowing through the battery pack 2 is smaller than a predetermined amount (for example, a predetermined current value that flows during external charging), the monitoring device 100 detects an abnormality in voltage detection based on the CCV difference, which is the difference between a first CCV of the first battery cell and a second CCV of the second battery cell (for example, steps S131 to S135).

In this configuration, when the current flowing through the battery pack 2 is smaller than the predetermined small value, an abnormality in voltage detection is detected based on the OCV difference, which is the difference between the first OCV of the first battery cell and the second OCV of the second battery cell. When the amount of variation in the current flowing through the battery pack 2 is less than the predetermined amount, an abnormality in voltage detection is detected based on the CCV difference, which is the difference between the first CCV of the first battery cell and the second CCV of the second battery cell. As a result, it is possible to detect deterioration in voltage detection accuracy.

(2) As shown in FIG. 2, the detection lines may include a first detection line electrically connected to a first electrode of the first battery cell, a second detection line electrically connected to a second electrode of the first battery cell that is different from the first electrode and to a first electrode of the second battery cell, and a third detection line electrically connected to a second electrode of the second battery cell (for example, the voltage detection lines connected to the terminals 12A to 12C). As described in step S132 of FIGS. 2 and 3, the monitoring device 100 may calculate, as the first CCV, a difference between the potential detected by the first detection line and the potential detected by the second detection line, and calculate, as the second CCV, a difference between the potential detected by the second detection line and the potential detected by the third detection line, and then calculate a CCV difference based on the calculated first and second CCVs. As shown in FIGS. 2 to 6A and 6B, the monitoring device 100 acquires, for each predetermined sampling period, a first combination of the first CCV and the current flowing through the first battery cell, and a second combination of the second CCV and the current flowing through the second battery cell, thereby obtaining a predetermined number of the first combinations and a predetermined number of the second combinations (for example, step S112). The monitoring device 100 calculates the internal resistances of the first and second battery cells from the predetermined numbers of the first and second combinations, respectively (for example, step S113), and calculates the first OCV and the second OCV from the first CCV and the second CCV using the calculated internal resistances (for example, step S114). The monitoring device 100 may then calculate an OCV difference from the calculated first and second OCVs (for example, steps S115 and S122).

In this configuration, the difference between the potential detected by the first detection line and the potential detected by the second detection line is calculated as the first CCV, and the difference between the potential detected by the second detection line and the potential detected by the third detection line is calculated as the second CCV. A CCV difference is then calculated from the calculated first and second CCVs. For each predetermined sampling period, a first combination of the first CCV and the current flowing through the first battery cell, and a second combination of the second CCV and the current flowing through the second battery cell, are acquired to obtain a predetermined number of the first combinations and a predetermined number of the second combinations. The internal resistances of the first and second battery cells are respectively calculated from the predetermined numbers of the first and second combinations, and the first OCV and the second OCV are calculated from the first CCV and the second CCV using the calculated internal resistances. An OCV difference is then calculated from the calculated first and second OCVs. As a result, the OCV difference can be appropriately calculated.

(3) As shown in FIG. 2, the monitoring device 100 may be configured to operate using, as a power source, a potential difference between one (for example, the voltage detection line connected to the terminal 12A) of the first detection line (for example, the voltage detection line connected to the terminal 12A) and the third detection line (for example, the voltage detection line connected to the terminal 12C), and another detection line (for example, the voltage detection line connected to the terminal 12N) that is different from the one detection line among the detection lines. With this configuration, deterioration in voltage detection accuracy can be detected even when electric power for the monitoring device 100 is supplied from the detection lines.

(4) As shown in FIG. 2, each detection line may include a terminal portion of a battery cell 10 (for example, terminal 12), a portion of the FPC 20 connected to the terminal portion, and a portion of a voltage detection line 101 that connects the FPC 20 to the monitoring device 100. The power lines of the monitoring device 100 may branch off from the portion of the voltage detection line 101.

This configuration makes it possible to reduce the size of the connectors 21, 22 of the FPC 20 as compared with a case where the power lines branch off from a portion other than the voltage detection line 101. This configuration also allows the connectors 21, 22 to be used without changing terminal arrangements between the voltage detection lines and the power lines. As a result, the manufacturing cost can be reduced.

The embodiment disclosed herein should be considered to be illustrative in all respects and not restrictive. The scope of the present disclosure is set forth in the claims rather than in the above description of the embodiment, and is intended to include all modifications within the meaning and scope equivalent to the claims.

What is claimed is:

1. A battery system configured to charge and discharge electric power, the battery system comprising:
a battery pack in which a plurality of battery cells is connected in series;
a plurality of detection lines each configured to detect a potential of a corresponding one of the battery cells; and
a processor configured to monitor voltages of the battery cells each determined from potentials of corresponding ones of the detection lines, wherein:
the battery cells include a first battery cell and a second battery cell; and
the processor is configured to
detect an abnormality in voltage detection based on an open-circuit voltage difference when a current flowing through the battery pack is smaller than a predetermined small value, the open-circuit voltage difference being a difference between a first open-circuit voltage of the first battery cell and a second open-circuit voltage of the second battery cell, and
detect an abnormality in voltage detection based on a closed-circuit voltage difference when an amount of variation in the current flowing through the battery pack is smaller than a predetermined amount, the closed-circuit voltage difference being a difference between a first closed-circuit voltage of the first battery cell and a second closed-circuit voltage of the second battery cell.

2. The battery system according to claim 1, wherein:
the detection lines include
a first detection line electrically connected to a first electrode of the first battery cell,
a second detection line electrically connected to a second electrode of the first battery cell that is different from the first electrode, and to a first electrode of the second battery cell, and
a third detection line electrically connected to a second electrode of the second battery cell; and
the processor is configured to
calculate, as the first closed-circuit voltage, a difference between a potential detected by the first detection line and a potential detected by the second detection line,
calculate, as the second closed-circuit voltage, a difference between the potential detected by the second detection line and a potential detected by the third detection line,
calculate the closed-circuit voltage difference based on the first closed-circuit voltage and the second closed-circuit voltage,
acquire, for each predetermined sampling period, a first combination of the first closed-circuit voltage and a current flowing through the first battery cell, and a second combination of the second closed-circuit voltage and a current flowing through the second battery cell, to obtain a predetermined number of the first combinations and a predetermined number of the second combinations,
calculate internal resistances of the first battery cell and the second battery cell from the predetermined number of the first combinations and the predetermined number of the second combinations, respectively,
calculate, using the internal resistances, the first open-circuit voltage and the second open-circuit voltage from the first closed-circuit voltage and the second closed-circuit voltage, respectively, according to OCV = CCV + IR, and
calculate the open-circuit voltage difference from the first open-circuit voltage and the second open-circuit voltage.

3. The battery system according to claim 1, wherein the processor is configured to detect an abnormality in voltage detection based on the open-circuit voltage difference when the current flowing through the battery pack is greater than or equal to the predetermined small value.

4. The battery system according to claim 2, wherein the processor is configured to operate using, as a power source, a potential difference between one of the first detection line and the third detection line and another detection line that is different from the one detection line among the detection lines.

5. The battery system according to claim 4, wherein:
the detection line includes a terminal portion of the battery cell, a portion of a flexible printed circuit connected to the terminal portion, and a wire portion connecting the flexible printed circuit and the processor; and
a power line of the processor branches off from the wire portion.
